(19) United States
(12) Patent Application Publication
(10) Pub. No.: US 2019/0221527 A1
(43) Pub. Date: Jul. 18, 2019

(54) REDISTRIBUTION SYSTEM WITH ROUTING LAYERS IN MULTI-LAYERED HOMOGENEOUS STRUCTURE AND A METHOD OF MANUFACTURING THEREOF

(71) Applicant: AIS Technology, Inc., Pleasanton, CA (US)

(72) Inventors: Raymond W. Bae, Pleasanton, CA (US); Yingmei Zheng, San Jose, CA (US)

(21) Appl. No.: 15/870,723

(22) Filed: Jan. 12, 2018

(51) Int. Cl. H01L 23/58; H01L 23/532; H01L 21/48; H01L 23/15

(52) U.S. Cl. CPC H01L 23/585; H01L 23/15; H01L 21/4885; H01L 23/5329

(57) ABSTRACT

An embodiment of the present invention provides a method and system of manufacturing a redistribution platform comprising: providing a substrate; patterning a first layer of a routing trace over the substrate; semi-curing a first translucent material around the first layer of the routing trace; testing the first layer of the routing trace; patterning a second layer of the routing trace over the first translucent material; and fully curing the first translucent material subsequent to the patterning of the second layer of the routing trace.

### CROSS-REFERENCE TO RELATED APPLICATIONS

This application contains subject matter related to a concurrently filed U.S. patent application by Raymond W. Bae and Yingmei Zheng, titled “REDISTRIBUTION SYSTEM WITH HOMOGENOUS NON-CONDUCTIVE STRUCTURE AND METHOD OF MANUFACTURE THEREOF.” The related application is assigned to AIS Technology, Inc. and is identified by docket number 50-002. The subject matter thereof is incorporated herein by reference thereto.

This application contains subject matter related to a concurrently filed U.S. patent application by Raymond W. Bae and Yingmei Zheng, titled “REDISTRIBUTION SYSTEM WITH UNIFORM CHARACTERISTIC MULTI-LAYERED HOMOGENOUS STRUCTURE AND METHOD OF MANUFACTURE THEREOF.” The related application is assigned to AIS Technology, Inc. and is identified by docket number 50-003. The subject matter thereof is incorporated herein by reference thereto.

This application contains subject matter related to a concurrently filed U.S. patent application by Raymond W. Bae, titled “REDISTRIBUTION SYSTEM WITH DENSE PITCH AND COMPLEX CIRCUIT STRUCTURES IN MULTI-LAYERED HOMOGENEOUS STRUCTURE AND A METHOD OF MANUFACTURING THEREOF.” The related application is assigned to AIS Technology, Inc. and is identified by docket number 50-005. The subject matter thereof is incorporated herein by reference thereto.

### TECHNICAL FIELD

An embodiment of the present invention relates generally to a redistribution system, and more particularly to a system with a redistribution layer with routing layers in a multi-layered homogeneous structure.

### BACKGROUND

Modern consumer and industrial electronics, cellular phones, mobile devices, and computing systems, are providing increasing levels of functionality to support modern life. Research and development in the existing technologies can take a myriad of different directions.

As users become more empowered with the growth of computing devices, new and old paradigms begin to take advantage of this new device space. There are many technological solutions to take advantage of this new device capability and device miniaturization. However, reliable testing of wafers through new devices has become a concern for manufacturers.

Thus, a need still remains for a redistribution system for testing of wafers through devices. In view of the ever-increasing commercial competitive pressures, along with growing consumer expectations and the diminishing opportunities for meaningful product differentiation in the marketplace, it is increasingly critical that answers be found to these problems. Additionally, the need to reduce costs, improve efficiencies and performance, and meet competitive pressures adds an even greater urgency to the critical necessity for finding answers to these problems.

Solutions to these problems have been long sought but prior developments have not taught or suggested any solutions and, thus, solutions to these problems have long eluded those skilled in the art.

### SUMMARY

An embodiment of the present invention provides a method of manufacturing of a redistribution platform comprising: providing a substrate; patterning a first layer of a routing trace over the substrate; semi-curing a first translucent material around the first layer of the routing trace; testing the first layer of the routing trace; patterning a second layer of the routing trace over the first translucent material; and fully curing the first translucent material subsequent to the patterning of the second layer of the routing trace.

An embodiment of the present invention provides a redistribution platform comprising: a substrate; a first layer of a routing trace patterned over the substrate; a first translucent material around the first layer of the routing trace; and a second layer of the routing trace (patterned over the first translucent material.

Certain embodiments of the invention have other steps or elements in addition to or in place of those mentioned above. The steps or elements will become apparent to those skilled in the art from a reading of the following detailed description when taken with reference to the accompanying drawings.

### BRIEF DESCRIPTION OF THE DRAWINGS

FIGS. 1A and 1B each depict a top view and a corresponding cross-sectional views of embodiments of a redistribution system along the lines 1A-1A and 1B-1B.

FIG. 2 is a top view of the redistribution platform of FIG. 1A of a redistribution system.

FIG. 3 is cross-sectional view of the redistribution platform of FIG. 2 with routing traces and redistribution layers formed thereon.

FIG. 4 is a top view of the substrate.

FIG. 5 is a cross-sectional view of the substrate along a line segment 5-5 of FIG. 4.

FIG. 6 is a cross-sectional view of the substrate in forming a redistribution layer.

FIG. 7 is the structure of FIG. 6 in forming the redistribution platform of FIG. 1A or the redistribution platform of FIG. 1B.

FIG. 8 is an embodiment of the redistribution platform with passive circuit elements formed therein.

FIG. 9 is an exemplary flow chart for of the redistribution system in an embodiment of the present invention.

FIG. 10 is a flow chart of a method of manufacturing of the redistribution system in an embodiment of the present invention

### DETAILED DESCRIPTION

The following embodiments are described in sufficient detail to enable those skilled in the art to make and use the invention. It is to be understood that other embodiments would be evident based on the present disclosure, and that system, process, or mechanical changes may be made without departing from the scope of an embodiment of the present invention.

In the following description, numerous specific details are given to provide a thorough understanding of the invention. However, it will be apparent that the invention may be practiced without these specific details. In order to avoid obscuring an embodiment of the present invention, some well-known circuits, system configurations, and process steps are not disclosed in detail.

The drawings showing embodiments of the system are semi-diagrammatic, and not to scale and, particularly, some of the dimensions are for the clarity of presentation and are shown exaggerated in the drawing figures. Similarly, although the views in the drawings for ease of description generally show similar orientations, this depiction in the figures is arbitrary for the most part. Generally, the invention can be operated in any orientation.

The designation and usage of the term first, second, third, etc. are for convenience and clarity and are not meant to limit a particular order. The steps or processes described can be performed in any order to implement the claimed subject matter.

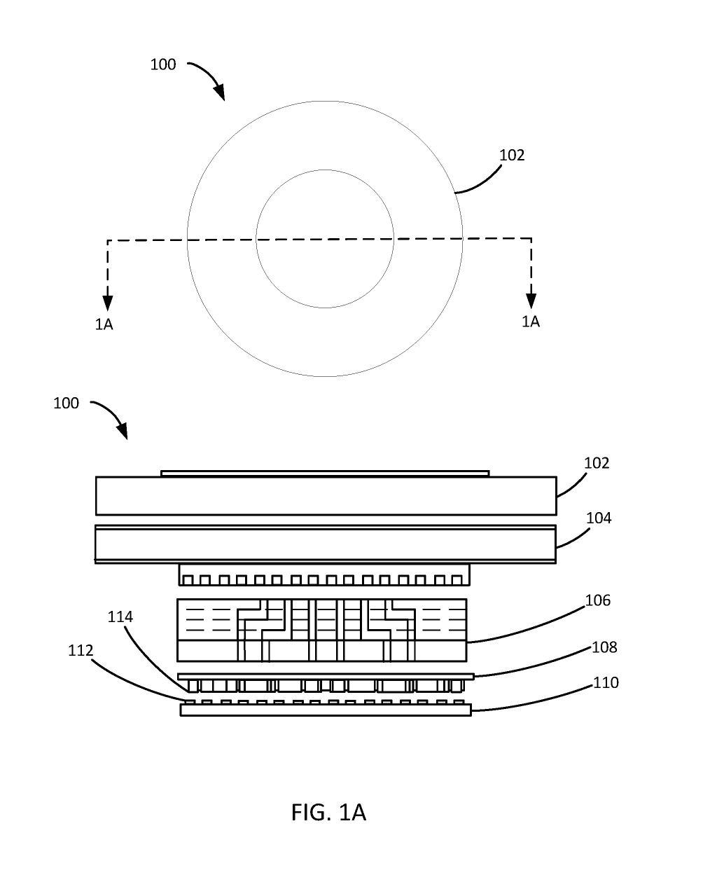

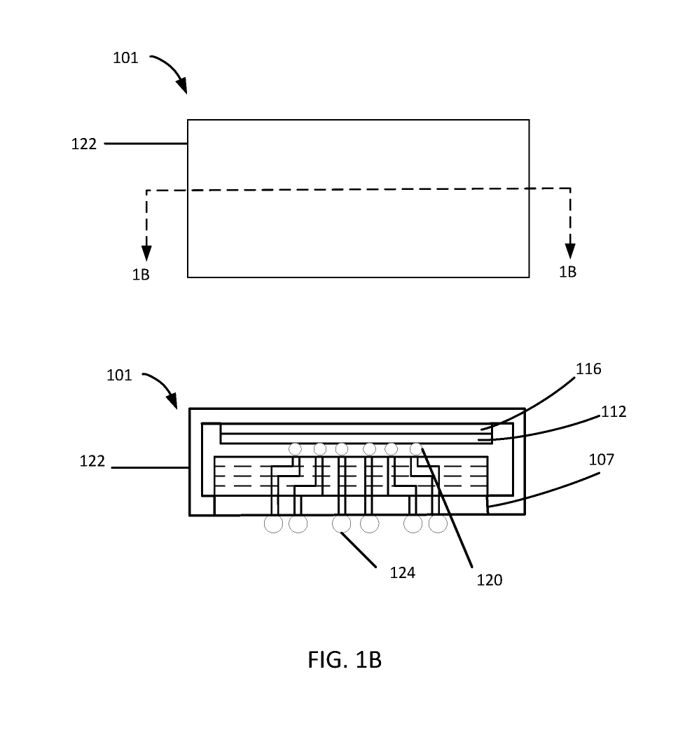

Referring now to FIGS. 1A and 1B, therein are shown in each a top view and a corresponding cross-sectional view of an embodiment of a redistribution system 100 along the lines 1A-1A and 1B-1B. FIG. 1A shows an embodiment of the redistribution system 100 as part of a test system, such as a wafer test system or an automated test environment (ATE). In this example, the redistribution system 100 includes a mechanical stiffener 102, a printed circuit board 104, a redistribution platform 106, and a probe card 108. In this embodiment as an example, the mechanical stiffener 102, the printed circuit board 104, the redistribution platform 106, and the probe card 108 are components for a system to test a semiconductor wafer 110. The semiconductor wafer 110 can be a processed silicon wafer. The semiconductor wafer 110 can include a die 112 with electronic components, such as circuits, integrated circuits, logic, or integrated logic fabricated thereon.

The probe card 108 is an interface for contacting test locations on the semiconductor wafer 110, the die 112, or a combination thereof. The probe card 108 can include probe heads 114 for contacting testing points or chip connecting pads on the components formed on the surface of the semiconductor wafer 110, the die 112, or a combination thereof.

The redistribution platform 106 is a structure for providing interconnection between two devices. For example, the redistribution platform 106 can be a space transformer, a redistribution structure for a multi-die package, or a combination thereof. In one embodiment, the redistribution platform 106 can provide electrical connectivity between the probe card 108 and the printed circuit board 104. The redistribution platform 106 can provide electrical and functional connectivity between the semiconductor wafer 110, the die 112, or a combination thereof, and the rest of the redistribution system 100.

Referring now to FIG. 1B, therein is shown a top view and schematic cross-sectional view of a further embodiment of the redistribution system 101 along the line 1B-1B of the top view of the redistribution system 101. The redistribution system 101 can be implemented as a package substrate in the further embodiment. In this example, the redistribution system 101 can include the redistribution platform 107, a die 112, a die attach adhesive 116, solder bumps 120, and a semiconductor cover 122.

In this example, the die 112 can be a semiconductor die, an integrated circuit, an optical device, or a combination thereof. The die 112 can attach to the semiconductor cover 122 directly using the die attach adhesive 116. In this example, the semiconductor cover 122 can be a heat sink, a hermetically sealing encasement, a radio frequency shield, or a combination thereof.

Solder bumps 120 can provide electrical connections between the die 112 and the redistribution platform 107 by providing electrical connections between electronic components fabricated on the die 112, such as circuits, integrated circuits, logic, integrated logic, and electrical connections on one side of the redistribution platform 107. In this example, the solder bumps 120 are describe as electrical interconnects and not limited to solder material.

Solder balls 124 can be placed on a second side of the redistribution platform 107 and provide electrical connections between the redistribution platform 107 and the external devices such as a probe card 108, a printed circuit board 104, or a combination thereof. In this example, the solder balls 124 are describe as electrical interconnects and not limited to solder material. Details of the testing and the redistribution platform 106 of FIG. 1A and the redistribution platform 107 of FIG. 1B will be discussed below.

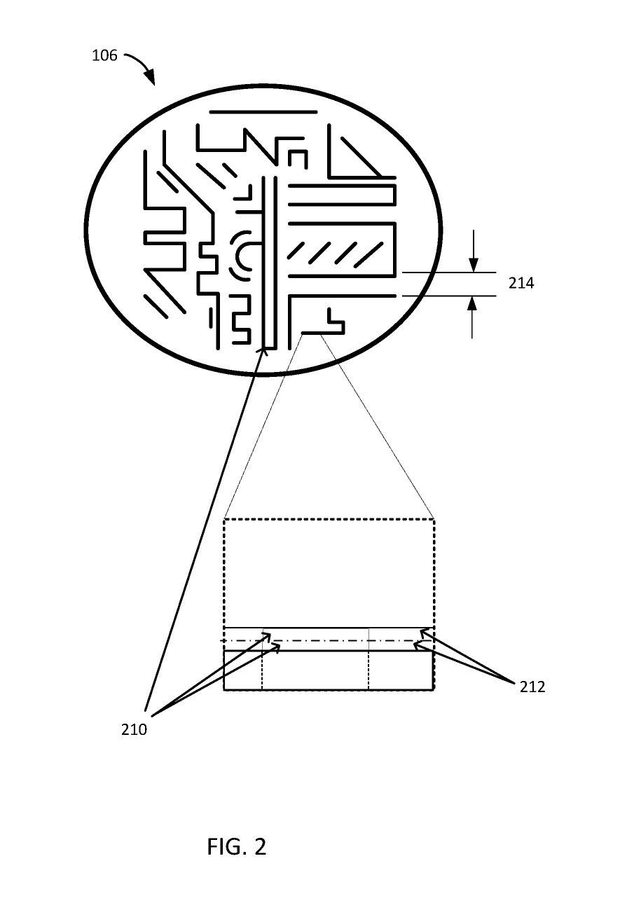

Referring now to FIG. 2, therein is shown a top view of the redistribution platform 106 of FIG. 1A of the redistribution system 100. FIG. 2 can also represent the redistribution platform 107 with respect to the embodiment shown in FIG. 1B. For convenience and brevity, reference will be made to the redistribution platform 106 of FIG. 1A throughout this specification, however descriptions apply similarly to, and can be incorporated for the embodiment shown in FIG. 1B.

In one embodiment, the redistribution platform 106 can include layers as seen by the expanded view of a portion of the redistribution platform 106. The layers can include routing traces 210 and a homogenous dielectric structure 212 built on top of a ridged foundation or base layer. Details of the layers will be discussed below.

As an example, the routing traces 210 are one or more continuous conductive traces that extend throughout the redistribution platform 106. The one or more routing traces 210 can be connected together either in their entirety to form one large routing trace 210, partially to form separate but connected routing traces 210, or can be isolated from one another to form individual and isolated routing traces 210 separate from any other routing trace 210.

For example, the routing traces 210 can provide connection pathways between connection points on the printed circuit board 104 of FIG. 1A and connection points of the probe card 108. The redistribution platform 106 can also provide a transition between the printed circuit board 104 and the probe card 108. The transition can include different geometries of electrical connection, different densities, different connection points, size of connections, number of routing traces 210, signal assignments, ground assignments, power assignments, or a combination thereof.

As a specific example, the routing traces 210 can provide connection pathways between the wider geometries and connection points on the printed circuit board 104 of FIG. 1A to the smaller geometries and connection points of the probe cards 108. Alternatively, the routing traces 210 can provide connection pathways between smaller geometries and connection points on the die 112 of FIG. 1B to wider geometries and connection points to external devices, such as the probe cards 108 or printed circuit board 104. A portion of the routing traces 210 can be exposed from a surface of the homogenous dielectric structure 212. The routing traces 210 can include a conductive material including, but are not limited to, metals, such as elemental copper, silver, or gold, or metallic alloys, such as copper alloys, silver alloys, or gold alloys.

The routing traces 210 can be used to transmit electrical signals throughout the redistribution platform 106. For example, in one embodiment, the routing traces 210 can facilitate the transmission of electrical signals from the printed circuit board 104 to the probe card 108. The routing traces 210 can also provide shielding of electrical signals by surrounding other routing traces 210 used for signal transmission and provide grounds for the routing traces 210. For example, the routing traces 210 can achieve pitches 214 on the redistribution platform 106 on a scale ranging from less than or equal to 20 micrometers. As a result, the electrical signals transmitted through the one or more routing traces 210 can cause electromagnetic interference with one another. Pitch 214 refers to the shortest measure between the center to center distance between features, such as the routing traces 210, of the redistribution platform 106.

In one embodiment, one or more routing traces 210 can be used to provide grounding and to function as ground traces so that the signals along other routing traces 210 transmitting signals can be shielded from interfering electromagnetic signals in order to provide improved signal quality throughout the redistribution platform 106.

The routing traces 210 can be shaped or patterned in a layered fashion. For example, the routing traces 210 can be shaped or patterned following a deposition phase. The deposition phase includes the deposition or buildup of a conductive material in mold channels. Details of the deposition phase and shaping or patterning of the routing traces 210 will be discussed below.

The homogenous dielectric structure 212 is a non-conductive material, for example a dielectric material that encases the routing traces 210. The homogenous dielectric structure 212 can be an electrically insulating material that provides insulation between each of the routing traces 210. For example, the homogenous dielectric structure 212 can be a structure including a polymer material or polyimide. The homogenous dielectric structure 212 can be transparent or translucent, enabling the visibility of the routing traces 210 through the homogenous dielectric structure 212.

Transparent or translucent refers to allowing light to pass through. As an example, an object can be seen, at least partially, through a translucent material. As another example, an object can be seen, potentially distinctly, through a transparent material. As an example, the homogenous dielectric structure 212 can be formed with multiple layers. Each of the layers can be formed as a single layer of the homogeneous dielectric structure 212 and each layer including one or more of the routing traces 210. As the homogeneous dielectric structure 212 with multiple layers, the transparent properties of the end structure allows the routing traces 210 from each layer to be seen from other layers. Details of the redistribution platform 106 will be discussed below.

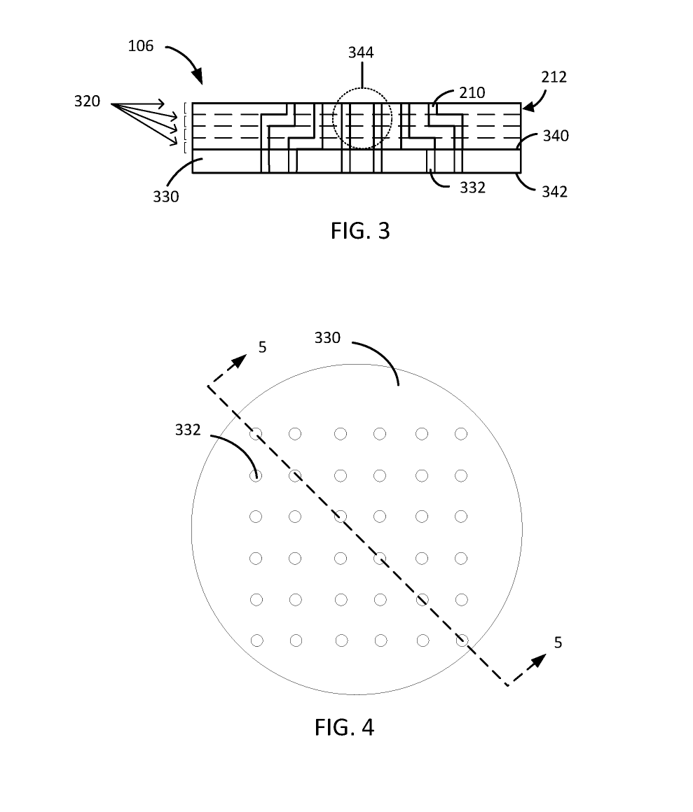

Referring now to FIG. 3, therein is shown a cross-sectional view of the redistribution platform 106 of FIG. 2 with routing traces 210 and redistribution layers 320 formed thereon. The cross-sectional view shown is an example and depicts the redistribution platform 106 including the redistribution layers 320 that can form the homogenous dielectric structure 212, the routing traces 210, and a substrate 330.

The substrate 330 can be a rigid foundation or base layer for the redistribution platform 106. The substrate 330 can include an electrically insulating material, such as a ceramic based or polymer composite based material. The substrate 330 can include a substrate first side 340 and a substrate second side 342. The substrate first side 340 and the substrate second side 342 can be the opposing surfaces of the substrate 330 that are facing away from one another.

The substrate 330 can include through substrate vias 332. The through substrate vias 332 are structures that extend from one surface of the substrate 330 to an opposing surface of the substrate 330. As an example, the through substrate vias 332 can include electrically conductive material, but are not limited to, metals, such as elemental copper, silver, or gold, or metallic alloys, such as copper alloys, silver alloys, or gold alloys.

The homogenous dielectric structure 212 can be formed from a plurality of redistribution layers 320, as shown by the dashed lines. The redistribution layers 320 are individual layers of the homogeneous dielectric structure 212 that have been chemically bonded to one another. Chemically bonded refers to the redistribution layers 320 having their atoms or ions bound into greater molecules or crystal as a result of one or more forces, especially ionic bonds, covalent bonds, metallic bonds, or a combination thereof. Chemical bond in the homogeneous dielectric structure 212 refers to attachment of the same material. Each of the redistribution layers 320 can include a portion of the routing traces 210 embedded therein.

The homogenous dielectric structure 212 is a uniform structure formed from a single material. For example, the homogenous dielectric structure 212 can be a homogenous polymer structure that does not include any interstitial material, such as fiber reinforcement. The lack of interstitial or embedded material enables the homogenous dielectric structure 212 to be translucent or transparent according to the properties of the dielectric material used to form the homogenous dielectric structure 212.

In one embodiment, the routing traces 210 can extend from the substrate 330 through the homogenous dielectric structure 212 and can be exposed from a surface of the homogenous dielectric structure 212 facing away from the substrate 330. The exposed portions of the routing traces 210 can include components, such as contact pads, to provide electrical connection to other devices, including test devices, such as the probe card 108 of FIG. 1A. The components can include the same or different conductive material as the routing traces 210. The components can include a conductive material including, but are not limited to, metals, such as elemental copper, silver, or gold, or metallic alloys, such as copper alloys, silver alloys, or gold alloys. In another embodiment, the exposed portions of the routing traces 210 can include components to provide electrical connection to another redistribution platform 106 including a substrate 330 with further routing traces 210.

In another embodiment, the routing traces 210 can be facing towards the substrate and can be connected to the through substrate vias 332 or be completely vertical from the through substrate vias 332. The term “horizontal” as used herein is defined as a plane parallel to the plane or surface of the substrate 330 that faces the semiconductor wafer 110 of FIG. 1A or the die 112 of FIG. 1B, regardless of its orientation. The term “vertical” refers to a direction perpendicular to the horizontal as just defined.

In another embodiment, the routing traces 210 can form structures along two dimensions, such as along horizontal plane, the vertical plane, or a plane at an angle obtuse to the horizontal or vertical planes. In a further embodiment, the routing traces 210 can form structures along three dimensions, such as along the horizontal plane and the vertical plane, along obtuse planes, along an obtuse plane and one of the vertical or horizontal planes, or a combination thereof.

The structures along two dimensions or three dimensions can span one or more redistribution layers 320. For example, in one embodiment the routing traces 210 can form plate structures along two dimensions or along three dimensions. The plate structures can be along the horizontal plane or the vertical plane.

As an example, the plate structures can be parallel to one another such that the plates form a vertical capacitor structure 344. The vertical capacitor structure 344 can, for example, perform the functions of a capacitor in an electrical circuit. The vertical capacitor structure 344 can form a passive circuit element that stores energy within the redistribution layers 320.

Continuing with the example, the vertical capacitor structure 344 can be connected to the through substrate vias 332 at the substrate first side 340 on one end and to a component, such as a contact pad to provide electrical connections at the portion of the routing trace 210 exposed from a surface of the homogenous dielectric structure 212. In the same embodiment, the material used for the homogeneous dielectric structure 212 can be placed between the two plates creating a capacitor with dielectric constant k. In another embodiment, a different dielectric material can be placed between the plate structures having a higher or lower dielectric constant than that of the homogeneous dielectric structure 212. The different dielectric material can be used to change the capacitance properties such that more or less energy can be stored between the plates of the vertical capacitor structure 344 than if material of the homogeneous dielectric structure 212 was to be used.

Also for example, the vertical capacitor structures 344 can also be used to provide power redistribution to different routing traces 210 throughout the redistribution platform 106. For example, the vertical capacitor structures 344 can be formed throughout one or more redistribution layers 320 and can have the plates connected to each other at the ends, at the same redistribution layer 320, or different redistribution layers 320. The plates can also be electrically connected to routing traces 210 in another redistribution layer 320 where the plates traverse to provide power to the routing trace 210 in the redistribution layer 320.

The flexible connection points to the vertical capacitor structures 344 allows for routing flexibility and reduce routing congestion for the routing traces 210. The flexible connection points also applies horizontal capacitor structure, which can be depicted as two routing traces 210 formed along the horizontal plane. Each of the plates of the horizontal capacitor structure can be depicted as a routing trace 210 along different layers of the redistribution platform 106. The layers can be adjacent and in direct contact to the other or separated by other layers. The connection to the plates of the horizontal capacitor structure can be at the same ends of the plates, at opposite ends, somewhere between the ends, or a combination thereof. The connections to the plates can be one or more routing traces 210 spanning one or more layers of the redistribution platform 106.

The vertical capacitor structure 344 is one of many structures that can be formed within the homogeneous dielectric structure 212. As examples, further structures that can be formed include passive and active circuit elements or structures. Further details regarding the various structures and circuit elements that can be formed within the homogeneous dielectric structure 212 will be discussed below. Also, components (not shown) or discrete circuit elements can be embedded within the redistribution platform 106 or the redistribution platform 107.

It has been discovered that the routing traces 210 forming structures, such as a vertical capacitor structure 344, allow for faster power transfer to components of the redistribution system 100 due to reduced paths to components as a result of these structures being embedded into the redistribution platform 106.

It has been further discovered that the routing traces 210 forming structures, such as a vertical capacitor structure 344, allow for direct point of access to different routing traces 210 across redistribution layers 320 leading to improved signal integrity and transmission for components of the redistribution system 100.

The substrate 330 can provide additional rigid support for the redistribution platform 106. More specifically as an example, the substrate 330 can provide structural support and rigidity for the homogenous dielectric structure 212, the routing traces 210, or a combination thereof. The through substrate vias 332 at the substrate second side 342 can be utilized for electrical connection to other devices, such as the printed circuit board 104 of FIG. 1A.

As a further example, the substrate 330 can be the homogeneous dielectric structure 212 formed previously. In this example, substrate 330 can be removed so only the homogeneous dielectric structure 212 along with the routing traces 210 and structures formed with the routing traces 210 remains while another instance of the homogeneous dielectric structure 212 is formed. The multiple instances of the homogeneous dielectric structure 212 can be the same or different.

Referring now to FIG. 4, therein is shown a top view of the substrate 330. The substrate 330 can be provided as a pre-fabricated structure for forming the redistribution platform 106. For example, the substrate 330 can include pre-formed components such as metallic bonding or contact pads at the surface of the substrate 330 to facilitate electrical connection between the routing traces 210 and the through substrate vias 332.

The substrate 330 can be formed from a number of different materials. For example, the substrate 330 can include a ceramic based material, such as a high temperature co-fired ceramic (HTCC) or a low temperature co-fired ceramic (LTCC). As another example, the substrate 330 can be formed from a polymer composite based material, such as a fiber reinforced polymer. As a specific example, the polymer based composite can include fiberglass reinforced epoxy laminates, such as Flame Retardant-4 (FR-4) grade printed circuit boards. As further example, the substrate 330 can be another instance or a design similar to the redistribution platform 106.

For illustrative purposes, the top view depicts the substrate 330 having a circular or round shape, although it is understood that the substrate 330 can have a different shape. For example, the substrate 330 can have an elliptical shape or a polygonal shape, such as a square, rectangle, or other polygonal shapes.

The substrate 330 can also include the through substrate vias 332. The through substrate vias 332 are structures that extend from one surface of the substrate 330 to an opposing surface of the substrate 330. As an example, the through substrate vias 332 can include electrically conductive material including metals, such as elemental copper, silver, or gold, or metallic alloys, such as copper alloys, silver alloys, or gold alloys. For illustrative purposes, the through substrate vias 332 are shown exposed at the surface of the substrate 330, however, it is understood that the through substrate vias 332 can be covered by a contact or bonding pad.

The number, pattern, location, pitch 214, diameter of the exposed portions, and size of the through substrate vias 332 are shown for illustrative purposes and are not drawn to scale. For example, the substrate 330 can include the through vias 332 having a pitch 214 on a scale less than or equal to 20 micrometers. As another example, the diameter of the through substrate vias 332 can be measured on a scale of tens of micrometers.

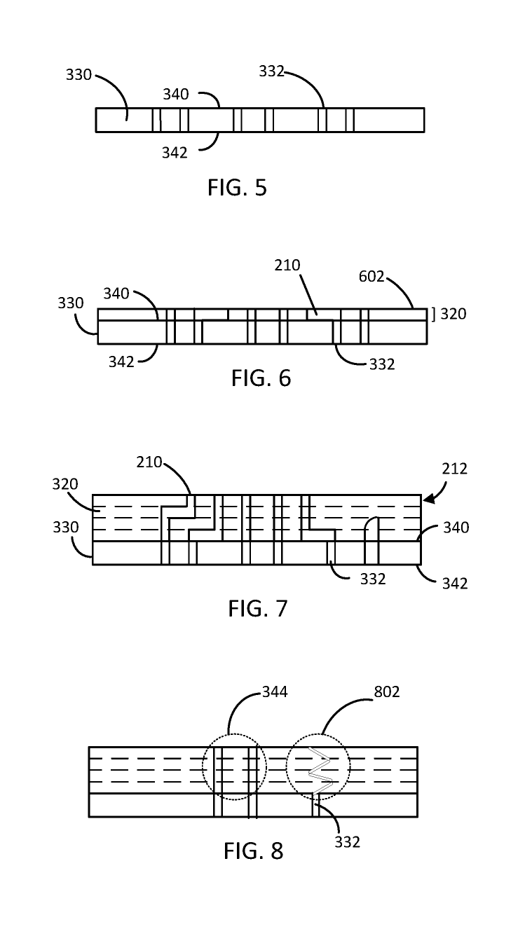

Referring now to FIG. 5, therein is shown a cross-sectional view of the substrate 330 along a line segment 5-5 of FIG. 4. The cross-sectional view depicts a portion of the substrate 330 with the through substrate vias 332. The through substrate vias 332 are optional and the substrate 330 can be implemented without the through substrate vias 332. The substrate 330 can include the substrate first side 340 and a substrate second side 342. The substrate first side 340 and the substrate second side 342 can be the opposing surfaces of the substrate 330 that are facing away from one another. The substrate first side 340 and the substrate second side 342 can be substantially parallel with one another.

The through substrate vias 332 can extend between the substrate first side 340 and the substrate second side 342 of the substrate 330. In one embodiment, the through substrate vias 332 can be connected to bond pads (not shown) or contact pads (not shown) at the substrate first side 340, the substrate second side 342, or a combination thereof. In another embodiment, the through substrate vias 332 can be exposed from the substrate first side 340, the substrate second side 342, or a combination thereof. The exposed portion of the through substrate vias 332 can be co-planar with the substrate first side 340, the substrate second side 342, or a combination thereof.

Optionally, the portions of the through substrate vias 332 at the substrate second side 342 can be electrically connected to conductive extensions (not shown). For example, the conductive extensions can be electrical connectors to other devices, such as a printed circuit board 104 of FIG. 1A or testing equipment.

Referring now to FIG. 6, therein is shown a cross-sectional view of the substrate 330 in forming a redistribution layer 320. The redistribution layer 320 can include the routing traces 210 and a polymer layer 602. The polymer layer 602 is a layer made of a polymer material. As a specific example, the polymer layer 602 can be an electrically insulating material which can cover portions of and electrically insulate each instance of the routing traces 210. The polymer layer 602 can also hermetically seal the routing traces 210 and the structures formed with the routing traces 210.

In one embodiment, in the first formation step of the redistribution layers 320, the first routing trace 210 is patterned over the substrate 330. In this example and phase of manufacturing, the routing traces 210 are a single layer of the redistribution platform 106. The routing traces 210 can be build up in each redistribution layer 320 sequentially and be connected to form the structures throughout the redistribution platform 106.

As an example, the routing traces 210 can be formed on the substrate 330. For example, the routing traces 210 can be formed directly on the substrate first side 340, the substrate second side 342, or a combination thereof. The routing traces 210 can be formed to electrically connect with the through substrate vias 332. The routing traces 210 can be formed to achieve uniform morphology between subsequent or preceding layers of routing traces 210. Uniform morphology refers to a seamless structure or shape formed by connecting subsequent layers of the routing traces 210 as opposed to being segmented along two dimensions or along three dimensions. Seamless refers to structures that are smooth and without seams or obvious joins.

The routing traces 210 can be formed by a number of different processes. For example, the routing traces 210 can be formed by processes including electrolytic deposition, diffusion, lithography, chemical mechanical planarization, or a combination thereof. As a specific example, the routing traces 210 can be formed by an electrolytic deposition process resulting in a uniform morphology between subsequent or preceding layers of routing traces 210.

The routing traces 210 can be formed into different geometric shapes or patterns to form structures. The structures can have a shape or a pattern in a linear configuration, a non-linear configuration, or a combination thereof. A linear configuration refers to a structure that is arranged in or extends along straight or nearly straight lines or along a plane. For example, a linear structure can include rectangles, squares, triangles, or a combination thereof including structure variations along two dimensions or along three dimensions.

A non-linear configuration refers to a structure that is not arranged along a straight or nearly straight line or a single plane. For example, a non-linear structure can include to any curved structure, circles, ellipses, ovals, a spring shape, or a combination thereof including structure variations along two dimensions or along three dimension.

The structures can also be shaped or patterned with the routing traces 210 formed to a configuration that is in the same or different pattern from the pattern of the routing traces 210 subsequent to or preceding the routing trace 210. For example, in one embodiment, a first routing trace 210 is patterned over the substrate 330 in a first configuration and the polymer layer 602 is placed around, hermetically encasing, or surrounding the routing trace 210, for one layer of the redistribution layers 320 and the routing trace 210 is patterned over the polymer layer 602 in a second configuration. In this embodiment, the first and second configurations can be configured to be the same or different shape or pattern or a combination thereof.

The routing traces 210 can also be formed from conductive material that can include metals, such as elemental copper, silver, or gold, or metallic alloys, such as copper alloys, silver alloys, or gold alloys. As a specific example, the routing traces 210 can include a material that is the same as or similar to the material of the through substrate vias 332.

The routing traces 210 can also be shaped or patterned by including the routing traces 210 formed using the same or different conductive material of the routing traces 210 subsequent to or preceding the routing trace 210. For example, in one embodiment, a first routing trace 210 is patterned over the substrate 330 using a gold alloy and the polymer layer 602 is placed around this instance of the routing trace 210, and a second instance of the routing trace 210 is patterned over the polymer layer 602 also using a gold alloy. In another embodiment, the second instance of the routing trace 210 can be patterned over the polymer layer 602 using a different metallic alloy such as a copper alloy or silver alloy.

It has been discovered that using the same conductive material to shape or pattern the routing traces 210 of subsequent or preceding layers of the routing traces 210 in the layered or stacked manner using the techniques described above allows the formation of larger uniform structures. This uniform structure provides better structural integrity as opposed to those using different conductive materials to shape or pattern the routing traces 210 of subsequent or preceding layers of the routing traces 210. In this example, this direct stack or direct layer approach allows the materials for the routing traces 210 or the routing traces 210 themselves to be formed directly to another instance of the routing traces 210 with no intervening elements or structures. Examples of intervening elements include different materials, such as tungsten, palladium, aluminum, for the routing traces formed with copper or copper alloy. Example of intervening structures include landing pads from the routing traces 210 to a separate via (not shown) formed for a different material. Instead, structural and electrical connectivity between the routing traces 210 at different layers can be formed with directly stacking and directly layering the structures with the process used to form the routing traces 210.

It has been further discovered that using the same conductive material to shape or pattern the routing traces 210 results in greater signal integrity throughout the redistribution system 100 because it reduces signal reflection at junctures where the routing traces 210 are attached between the redistribution layers 320 due to the uniform morphology between subsequent or preceding layers of the routing traces 210.

It has been discovered that by using the processes described earlier to achieve the pitch 214 on a scale of less than or equal to 20 micrometers, the redistribution platform 106 can achieve power reduction of the overall system due to the routing traces 210 being implemented to minimize length and junctions that are possible from tighter pitches 214.

It has been further discovered that the processes for the embodiments described earlier allows stacking or layering more numbers of the redistribution layers 320 for the redistribution platform 106 or the redistribution platform 107. The optical transparency or translucency allows for better inspection and alignment of stacking and layering the routing traces 210 over one another. The ability to stack the routing traces 210 directly over one another provides more precision to stack one layer over another.

It has been further discovered that with the techniques described above, the redistribution platform 106 can also provide circuits, such as passive circuits, active circuits, or a combination thereof through the formation of various linear and non-linear structures within the redistribution layers 320. Examples of passive circuits can include inductors, capacitors, resistors, circuit network formed with these circuit elements, or a combination thereof. Examples of active circuits include transistors, logic gates, circuitry formed with these circuit elements, or a combination thereof. Examples can include other structures, such as Microelectromechanical systems (MEMS), springs, coils, external contact pins, or a combination thereof.

Subsequent to forming the routing trace 210 in the first layer of the redistribution layers 320 over the substrate 330, the routing trace 210 can be tested to determine whether it functions properly and to verify that the routing trace 210 and the redistribution layer 320 satisfy one or more test conditions. Unlike semiconductor wafer manufacturing, the substrate 330 with the first layer of the redistribution layers 320 can be removed from the manufacturing line and tested. Semiconductor wafers cannot leave the manufacturing line and cannot be handled by humans since to avoid introducing impurities to the semiconductor wafer during the fabrication process. The impurities can cause defects resulting in faulty circuits or routing between circuit elements in the semiconductor wafers. The impurities can also impact infant mortality whereby the semiconductor wafer and the resulting semiconductor devices can pass initial functional and parametric testing but fail in the field prematurely. Premature failures are field failure and are very costly to fix, repair, or replace and devastating to the supplier of the semiconductor device in terms of market reputation and reliability.

Returning to testing the redistribution platform 106 or the redistribution platform 107 throughout the manufacturing process, the test conditions refer to one or more test cases in which the function, feature, quality, attribute, structural elements, or a combination thereof of the first layer of the redistribution layers 320, the first layer of the routing trace 210, or a combination thereof functions or meets the requirements as designed. As examples, the testing of the routing trace 210 can include verification for short circuits, open circuits, proper conduction, structural integrity, or a combination thereof. If the routing trace 210 passes the test conditions, the formation step can proceed to be covered by application of a liquid dielectric precursor material.

In the event that the routing trace 210 fails any of the test conditions, the routing trace 210 can be modified. The modification refers to the making of changes or engineering change order (ECO) to the routing trace 210 so as to resolve the test failure. The modification can include fixing design errors in the pattern of the routing traces 210, fixing inadvertent short circuits in the pattern of the routing traces 210, fixing inadvertent open circuit or poor conduction in the pattern of the routing traces 210, or a combination thereof.

The modifications can be performed in a number of ways. As an example, fixing a wrong pattern in the routing traces 210 can be performed by removing a portion of the routing traces 210 and replacing it. As a specific example, the removal of a portion of the routing traces 210 can be performed by forming a removal mask (not shown) over the portions not to remove and exposing the areas to remove. The masking process can be followed by a removal process, such as chemical etching or laser ablation, to remove the selected portions of the routing traces 210. This removal mask (not shown) can be removed and a correction mask can be formed covering the portions of the routing traces 210 to not modify while exposing a portion of this layer of the redistribution layers 320 for forming portions of the pattern for the routing traces 210. A replacement process can add portions of the routing traces 210 in the areas exposed by the correction mask.

Also for example, fixing an inadvertent short circuit in the routing traces 210 can be performed by making partial changes to the routing trace 210 by removing only portions of the routing trace 210 causing the short failure. Processes for fixing a short circuit can follow a similar process as described earlier. For brevity and as an example, the process can include a removal mask to remove the short circuit followed by another testing process.

Further for example, fixing an inadvertent open circuit or poor conduction can be performed by adding portions to the first routing trace 210. The substrate 330 can undergo a partial or full testing after the modifications to verify that each layer of the redistribution layers 320 meets or exceed design specifications. This process can be iterated as needed before continuing to process the next layer of the redistribution layers 320. The substrate 330 with this modified version of the redistribution layer 320 can undergo grinding or polishing.

Also for example, the testing can be done with one or more test devices, including testing devices that are the same as the testing devices used to test the semiconductor wafer 110, die 112, or the semiconductor cover 122, of FIGS. 1A and 1B. Other testing devices can include probes, contact pads, pressure sensors, or a combination thereof that can be used to conduct the testing.

In another embodiment, one test condition can check for structural integrity of the routing trace 210 at this stage of manufacturing the redistribution platform 106 or the redistribution platform 107. In the event that the test reveals that there are cracks, discontinuities, or other weaknesses in the routing trace 210 forming the structure, all or a portion of the first routing trace 210 can be removed and replaced using the techniques described above.

In another embodiment, one test condition can check to see if the dimension or surface area of the routing trace is sufficient to ensure sufficient surface area for conduction of high speed signals, for example in the gigahertz (GHz) range. In the event that the test reveals that high speed signals result in an increase in the effective resistance of the routing trace 210 to appropriately accommodate “skin-effect”, where the electrical current conducts at the surface of a conductor as opposed to within the conductor, all or a portion of the routing trace 210 can be removed and replaced using the techniques described above.

In another embodiment, where circuit elements are embedded or formed in the redistribution platform 106 or the redistribution platform 107, one test condition can check to see if the circuit element or a portion thereof is properly placed within the redistribution layer 320. For example, where a vertical capacitor structure 344 or a portion thereof is being formed in a redistribution layer 320 by depositing the routing trace 210, one test can determine whether the spacing between two portions of the routing trace 210 forming the walls of vertical capacitor structure 344 that will be used to form plates of the vertical capacitor structure 344 are sufficiently spaced. In the event that the test reveals that the spacing is improper, all or a portion of the routing trace 210 can be removed and replaced using the techniques described above.

Continuing with the example, a second layer of the redistribution layers 320 can be formed over, directly on, or a combination thereof the routing trace 210 in the first layer of the redistribution layers 320. The second layer can commence manufacturing once the first layer of the first routing trace 210 pass all test conditions for that particular layer and the first routing trace 210 and the substrate 330 can be covered by application of a liquid dielectric precursor material.

The liquid dielectric precursor material can be an organic solution or organic suspension. For example, the liquid dielectric material can be a solution of monomer or oligomer molecules for a polymer, suspended or dissolved in a solvent. The liquid dielectric precursor material can be a solution that includes monomer or oligomer molecules as a precursor for one of a variety of different polymer materials. For example, the liquid dielectric precursor material can be a precursor for polyimide based polymers, epoxy based polymer, or other types of polymers. The dielectric precursor material can form the polymer layer 602.

In a further specific example, the liquid dielectric precursor material can include monomer or oligomer molecules that are capable of polymerization through a condensation reaction. In yet a further specific example, the liquid dielectric precursor material can include cross-linking or end-cap monomer units, which can be involved in cross-linking in a subsequent curing phase. The end-cap monomer units are molecules that can stop the polymerization reaction of a particular molecule.

The liquid dielectric precursor material can be applied in a number of ways. For example, the liquid dielectric precursor material can be applied through a spin-coating process to cover the substrate 330, the routing traces 210, or a combination thereof. As another example, the liquid dielectric precursor material can be applied through a method that can provide uniform distribution and thickness of the liquid dielectric precursor material across the substrate 330.

In forming a third layer of the redistribution layers 320, the liquid dielectric precursor material can be partially or fully cured to form the polymer layer 602. The liquid dielectric precursor material can be heated to a polymerization temperature and for a time period that promotes polymer molecule chain building from the monomer or oligomer molecules. However, the polymerization temperature is different from a cross-linking temperature, which is a temperature at which cross-linking between the end-cap or cross-linking monomer molecules occurs. More specifically as an example, the polymerization temperature can be a lower temperature than the temperature for cross-linking of an end-cap or cross-linking monomer molecules. The temperature at which the cross-linking occurs is the temperature in which the homogeneous dielectric structure 212 is formed is referred to as the temperature in which the polymer layer 602 is fully cured. The temperature to form the polymer molecules of the polymer layer 602 prior to forming the homogenous dielectric structure 212 is referred to as the temperature at which the polymer layer 602 is semi-cured.

The polymer molecules of the polymer layer 602 can be formed with a length or molecular weight that is statistically proportional to the number of monomer units and the end-cap units in the liquid dielectric precursor material. Optionally, the substrate 330 and the liquid dielectric precursor material can be agitated through vibration during the curing phase to facilitate removal of volatile components, such as gas molecules, formed during the polymerization of the liquid dielectric precursor material to prevent void formation in the polymer layer 602 and at the interface between the routing traces 210 and the polymer layer 602.

In forming a fourth layer of the redistribution layers 320, a portion of the polymer layer 602 can be removed to form an instance of the redistribution layers 320. More specifically, portions of the polymer layer 602 facing away from the substrate 330 can be removed to expose the portions of the routing traces 210 facing away from the substrate 330. The surface of the polymer layer 602 facing away from the substrate 330 can be planarized to be co-planar with the portions of the routing traces 210 exposed from redistribution layers 320 and facing away from substrate 330. As an example, the redistribution layers 320 can be formed to have a thickness ranging 10 micrometers or more. In the example illustrated, the thickness of the redistribution layers 320 can be measured from the interface between the substrate 330 and the instance of the redistribution layers 320, such as the substrate first side 340, to the surface of the instance of the redistribution layers 320 facing away from the substrate 330.

The polymer layer 602 can be transparent or translucent. The transparent or translucent characteristic can be based on the cured properties of the liquid dielectric precursor material used to form the polymer layer 602. The transparent or translucent characteristic of the polymer layer 602 enables the routing traces 210 of the redistribution layers 320 and objects underneath or behind the polymer layer 602, such as the substrate 330 or previously formed instances of the redistribution layers 320 to be visible through the polymer layer 602.

It has been discovered that the transparent or translucent characteristic of the polymer layer 602 enables the efficient testing and determination of whether subsequent routing traces 210 are placed properly on top of one another due to the ability to optically inspect whether routing traces 210 placed on top of each other are geometrically aligned throughout the redistribution platform 106, leading to faster assembly and manufacturing times, and leading to higher yields as compared to current semiconductor manufacturing processes, printed circuit board (PCB) manufacturing processes, or multilayer organic (MLO) manufacturing processes.

Referring now to FIG. 7, therein is shown the structure of FIG. 6 in forming the redistribution platform 106 of FIG. 1A or the redistribution platform 107 of FIG. 1B. For brevity, FIG. 7 will be described with the embodiment shown in FIG. 1A for the redistribution platform 106 without loss in generality and applicability to the redistribution platform 107.

The cross-sectional view depicts the redistribution platform 106 formed following a sequential formation of a plurality of the redistribution layers 320. Testing of the routing traces 210 can be done for each redistribution layer 320 formed in a manner similar to that described with respect to FIG. 6.

Following the formation of the final instance of the redistribution layer 320, the plurality of the polymer layer 602 can be further processed to form the homogenous dielectric structure 212 by fully curing the plurality of the polymer layer 602. The homogenous dielectric structure 212 can be fully cured and formed through cross-linking between the polymer layer 602 of the redistribution layers 320. As a more specific example, the homogenous dielectric structure 212 can be formed by heating the polymer layer 602 to a cross-linking temperature, or a temperature that facilitates or promotes the formation of chemical bonds between the end-caps throughout the polymer layer 602 and at the interface between adjacent instances of the polymer layer 602 to form a single continuous structure. The cross-linking temperature can be different from the temperature to form the polymer molecules of the polymer layer 602 as described in FIG. 6. In general, the cross-linking temperature is higher than that of the temperature for polymerization of the liquid dielectric precursor material of FIG. 6. The cross-linking temperature can vary based on the end-cap unit used for forming the cross-linking bonds between the polymer molecules.

It has been discovered that the homogenous dielectric structure 212 formed by cross-linking of polymer molecules between the polymer layer 602 eliminates the need for an intervening bonding material. More specifically, forming of the cross-linking chemical bonds between the polymer molecules in the adjacent instances of the polymer layer 602 eliminates the need for adhesive or bonding material to form the homogenous dielectric structure 212.

It has been further discovered that by forming the homogenous dielectric structure 212 in the manner described above allows the redistribution platform 106 to become significantly less prone to warpage because the redistribution layers 320 are built layer by layer and contain routing traces 210 already encased in the polymer layer 602 prior to the polymer layer 602 being heated to form the homogeneous dielectric structure 212 rather than existing semiconductor manufacturing technologies which form the structures prior to encasing them in polymer layer 602, and as a result the routing traces 210 and other components within the redistribution layers 320 are less prone to cracking due to thermal expansion of the polymer layer 602 when forming the homogeneous dielectric structure 212.

It has been further discovered that by forming the homogenous dielectric structure 212 in this manner the redistribution layers 320 exhibit high levels of planarity as compared to current semiconductor manufacturing processes, printed circuit board (PCB) manufacturing processes, or multilayer organic (MLO) manufacturing processes. Planarity is critical to testing the semiconductor wafer 110 of FIG. 1A, the die 112 of FIG. 1B, or a combination thereof. Warpage, such as poor planarity, of the redistribution platform 106 results in inconsistent contacts to the semiconductor wafer 110, the die 112, or a combination thereof resulting in decreased reliability for electrical conduction, functionality, and tests.

Referring now to FIG. 8, therein is shown an embodiment of the redistribution platform 106 containing some of the passive circuit elements formed therein. FIG. 8 shows an embodiment in which the redistribution platform 106 contains the vertical capacitor structure 344 of FIG. 3 and an inductor structure 802, as examples of passive circuit elements. The inductor structure 802 can be formed as a spring structure spanning through one or more redistribution layers 320. The circuit elements can be formed in a layer by layer manner as described above and can function independently or be connected to form circuits within the redistribution platform 106.

It has been discovered that forming circuit elements within the redistribution layers 320 of the redistribution platform 106 using the techniques described above allows for robust testing of semiconductor wafers 110, dies 112, or semiconductor packages 122, due to the ability to build complex circuits directly within the redistribution platform 106. The manufacturing of the passive circuit elements within the redistribution platform 106 enable placing the passive circuit elements closer to the point of contact to the semiconductor wafer 110, the die 112, or a combination thereof.

It has been further discovered that the ability to form circuit elements within the redistribution platform 106 results in faster power transfer to components of the redistribution system 100 due to reduced power paths to components of the redistribution system 100 resulting in faster signal processing times for testing circuits built within the redistribution platform 106.

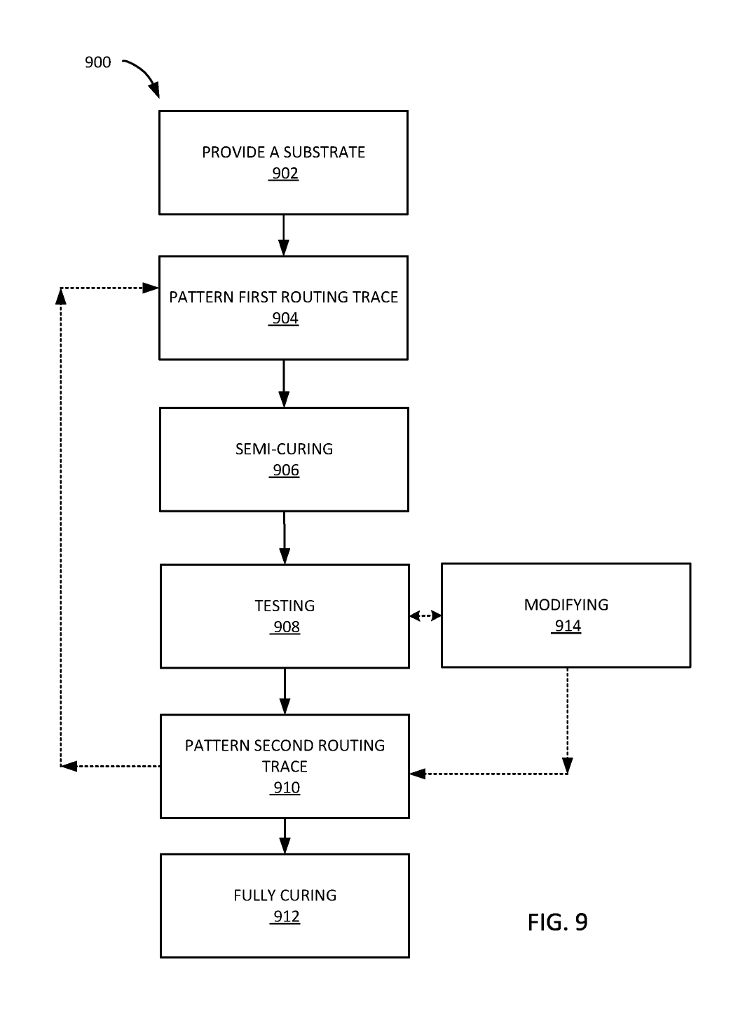

Referring now to FIG. 9, therein is shown a flow chart for the redistribution system in an embodiment of the present invention. The example shown in FIG. 9 can include the processes, components, or steps described with respect to FIGS. 5, 6, 7, 8, or a combination thereof. In one embodiment, the flow chart can include providing a substrate 330 in box 902; patterning a first layer of the routing trace 210 over the substrate 330 in box 904; semi-curing a first translucent material around the routing trace 210 in box 906; testing the routing trace 210 in box 908; patterning a second layer of the routing trace 210 over the first translucent material of the first layer of the redistribution layers 320 in box 910; optionally repeat the process from box 904 until the number of redistribution layers 320 has been formed; and fully curing the first translucent material subsequent to the patterning of the second layer of the routing trace 210 in box 912.

In another embodiment, the flow chart can include providing a substrate 330 in box 902; patterning a first layer of the routing trace 210 over the substrate 330 in box 904; semi-curing a first translucent material around the first layer of the routing trace 210 in box 906; testing the first layer of the routing trace 210 in box 908; modifying the first layer of the routing trace 210 upon failure of a test condition during the testing of the first layer of the routing trace 210 in box 914; repeating the testing in the box 908 until all the test for the layer of the redistribution layers 320 passes; patterning a second layer of the routing trace 210 over the first translucent material in box 910; optionally repeat the process from box 904 until the number of redistribution layers 320 has been formed; and fully curing the first translucent material subsequent to the patterning of the second layer of the routing trace 210 in box 912.

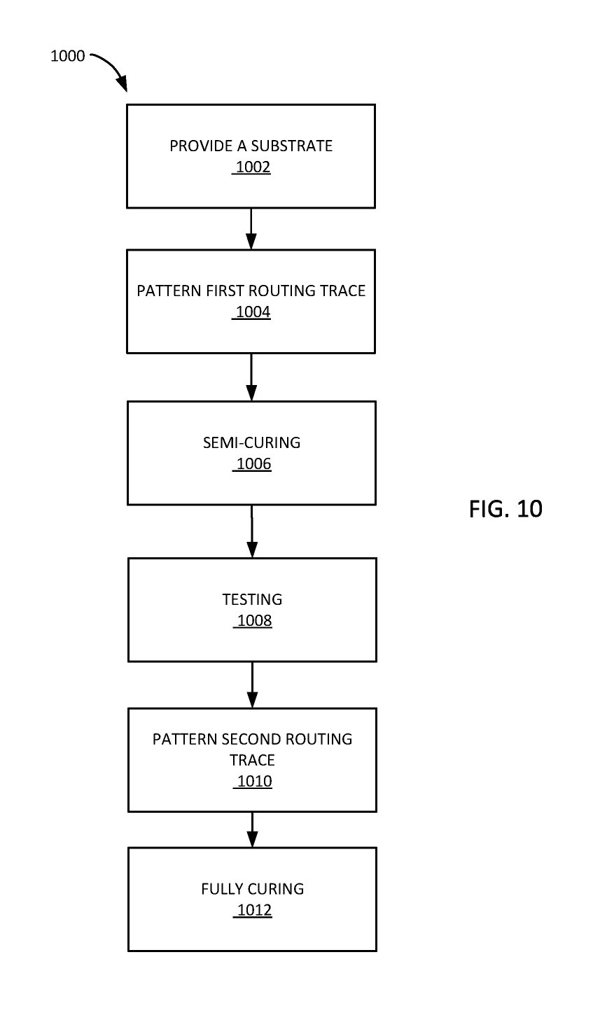

Referring now to FIG. 10, therein is shown a flow chart of a method 1000 of manufacturing of the redistribution system 100 in an embodiment of the present invention. The method 1000 can a providing a substrate 330 in box 1002; patterning a first layer of the routing trace 210 over the substrate 330 in box 1004; semi-curing a first translucent material around the routing trace 210 in box 1006; testing the routing trace 210 in box 1008; patterning a second layer of the routing trace 210 over the first translucent material of the first layer of the redistribution layers 320 in box 1010; optionally repeat the process from box 1004 until the number of redistribution layers 320 has been formed; and fully curing the first translucent material subsequent to the patterning of the second layer of the routing trace 210 in box 1012.

The resulting method, process, apparatus, device, product, and/or system is cost-effective, highly versatile, accurate, sensitive, and effective, and can be implemented by adapting components for ready, efficient, and economical manufacturing, application, and utilization. Another important aspect of an embodiment of the present invention is that it valuably supports and services the historical trend of reducing costs, simplifying systems, and increasing performance.

These and other valuable aspects of an embodiment of the present invention consequently further the state of the technology to at least the next level. While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations that fall within the scope of the included claims. All matters set forth herein or shown in the accompanying drawings are to be interpreted in an illustrative and non-limiting sense.

1. A method of manufacturing of a redistribution platform comprising:
providing a substrate;
patterning a first layer of a routing trace over the substrate;
semi-curing a first translucent material around the first layer of the routing trace;
testing the first layer of the routing trace;
patterning a second layer of the routing trace over the first translucent material; and
fully curing the first translucent material subsequent to the patterning of the second layer of the routing trace.

2. The method as claimed in claim 1 further comprising modifying the first layer of the routing trace upon failure of a test condition during the testing of the first layer of the routing trace.

3. The method as claimed in claim 1 wherein patterning the second layer of the routing trace includes patterning in a different configuration from the first layer of the routing trace.

4. The method as claimed in claim 1 wherein patterning the second layer of the routing trace includes patterning in a same configuration as the first layer of the routing trace.

5. The method as claimed in claim 1 wherein patterning the second layer of the routing trace includes patterning using an identical conductive material as the first layer of the routing trace.

6. The method as claimed in claim 1 wherein patterning the second layer of the routing trace includes electrolytic depositing an identical conductive material as the first layer of the routing trace.

7. The method as claimed in claim 1 wherein patterning the second layer of the routing trace includes patterning an exposure of the second layer of the routing trace from the surface of the first translucent material for testing the second layer of the routing trace, the first layer of the routing trace, or a combination thereof.

8. The method as claimed in claim 1 wherein patterning the second layer of the routing trace includes forming a non-linear structure with the first layer of the routing trace and the second layer of the routing trace.

9. The method as claimed in claim 1 wherein patterning the first layer of the routing trace or patterning the second layer of the routing trace includes patterning a non-linear structure with the first layer of the routing trace or the second layer of the routing trace, respectively.

10. The method as claimed in claim 1 wherein patterning the first layer of the routing trace includes patterning on a ceramic substrate.

11. A redistribution platform comprising:
a ceramic substrate;
a first layer of a routing trace patterned over the substrate;
a first translucent material around the first layer of the routing trace; and
a second layer of the routing trace patterned over the first translucent material, wherein the first layer of the routing trace and the second layer of the routing trace are electrically connected to form a portion of a circuit formed above the ceramic substrate.

12. The redistribution platform as claimed in claim 11 wherein the second layer of the routing trace includes a pattern in a different configuration from the first layer of the routing trace.

13. The redistribution platform as claimed in claim 11 wherein the second layer of the routing trace includes a pattern in a same configuration as the first layer of the routing trace.

14. The redistribution platform as claimed in claim 11 wherein the second layer of the routing trace includes an identical conductive material as the first layer of the routing trace.

15. The redistribution platform as claimed in claim 11 wherein the second layer of the routing trace is patterned by using an identical conductive material as the first layer of the routing trace to achieve uniform morphology between the first layer of the routing trace and the second layer of the routing trace.

16. The redistribution platform as claimed in claim 11 wherein the first translucent material includes a surface providing an exposure of the second layer of the routing trace to provide electrical connection to a test device.

17. The redistribution platform as claimed in claim 11 wherein the second layer of the routing trace includes a non-linear structure formed with the first layer of the routing trace.

18. The redistribution platform as claimed in claim 11 wherein the first layer of the routing trace or the second layer of the routing trace is a non-linear structure.

19. The redistribution platform as claimed in claim 11 further comprising a second translucent material around the second layer of the routing trace hermetically encasing the first layer of the routing trace and the second layer of the routing trace.

20. The redistribution platform as claimed in claim 11 wherein the first translucent material includes a polymer material.
